(19) United States
(12) Patent Application Publication
(10) Pub. No.: US 2018/0084638 A1
(43) Pub. Date: Mar. 22, 2018

(54) PCB MICROSTRIP PROPAGATION DELAY MATCHING THROUGH CONTROL OF TRACE WIDTH

(71) Applicants: Marko Antonic, Kanata (CA); Robert Bisson, Kanata (CA)

(72) Inventors: Marko Antonic, Kanata (CA); Robert Bisson, Kanata (CA)

(73) Assignee: Ciena Corporation, Hanover, MD (US)

(21) Appl. No.: 15/270,893

(22) Filed: Sep. 20, 2016

(51) Int. Cl. H05K 1/02; H01P 3/08; H03K 5/159

(52) U.S. Cl. CPC H05K 1/0245; H03K 5/159; H01P 3/08

(57) ABSTRACT

A differential pair propagation delay matched microstrip transmission line manufactured on a printed circuit board (PCB) includes a first trace including a strip of conductor in air, a second trace including a strip of conductor in the air positioned adjacent to and closely spaced apart from the first trace, a conductive reference plane disposed adjacent the first trace and the second trace, and a layer of dielectric material that separates the first trace and the second trace from the conductive reference plane, such that electric fields fringing out of the first trace and second trace pass through the air and the layer of dielectric material. A width of at least one of the first trace and the second trace is adjusted to match signal propagation times of the first and second traces.

### FIELD OF INVENTION

The present invention relates generally to transmission lines and transmission line features, in particular propagation delay matching of microstrip transmission lines through control of trace width.

### BACKGROUND OF INVENTION

A microstrip is a type of transmission line manufactured on printed circuit boards (PCBs). A microstrip comprises a strip of conductor (trace) on an outer layer referenced to a conductive plane separated by a layer of dielectric material. Microstrips are frequently used on PCBs to carry various signals. In some cases, these signals are timed with other signals such that pulses arrive at destinations simultaneously. Furthermore, these signals can be differential, using two adjacent microstrips as a differential microstrip, in which case each microstrip must be matched such that the signal and its complement arrive at a destination simultaneously. For such configurations, not meeting these timing requirements can cause the interface to operate unexpectedly. The result may be closed eye patterns that indicate transmission is impossible or improper signal timing such as setup and hold times which mean pulses can be clocked before they have arrived at the destination device. As the signaling speed of these signals increase, the importance of meeting these matching requirements also increases.

### SUMMARY OF INVENTION

In one aspect, one or more embodiments of the invention relate to a differential pair propagation delay matched microstrip transmission line manufactured on a printed circuit board (PCB) that includes a first trace including a strip of conductor in air, a second trace including a strip of conductor in the air positioned adjacent to and closely spaced apart from the first trace, a conductive reference plane disposed adjacent the first trace and the second trace, and a layer of dielectric material that separates the first trace and the second trace from the conductive reference plane, such that electric fields fringing out of the first trace and second trace pass through the air and the layer of dielectric material, in which a width of at least one of the first trace and the second trace is adjusted to match signal propagation times of the first and second traces.

In another aspect, one or more embodiments of the invention relate to a single-ended propagation delay matched microstrip transmission line manufactured on a printed circuit board (PCB) that includes a trace including a strip of conductor in air, a conductive reference plane disposed adjacent the trace, and a layer of dielectric material that separates the trace from the conductive reference plane, such that the electric field fringing out of the trace passes through the air and the layer of dielectric material, in which a width of the trace is adjusted to match signal propagation time thereof with another signal.

In another aspect, one or more embodiments of the invention relate to a method of propagation delay matching a microstrip transmission line that includes determining a time criteria for a circuit, determining one or more traces in the circuit to be microstrips, and adjusting a width of at least one of the microstrip traces based on the time criteria to obtain a desired propagation delay.

Other aspects and advantages of the invention will be apparent from the following description and the appended claims.

### BRIEF DESCRIPTION OF DRAWINGS

Embodiments of the invention will be described with reference to the accompanying drawings. However, the accompanying drawings illustrate only certain aspects or implementations of one or more embodiments of the invention by way of example and are not meant to limit the scope of the claims.

FIG. 1 shows a block diagram of a system including a differential pair of traces in accordance with one or more embodiments.

FIG. 2 shows a block diagram of a system including single-ended traces in accordance with one or more embodiments.

FIG. 3 illustrates electric field lines fringing out of microstrip traces.

FIG. 4 illustrates a cross section view of a microstrip trace in accordance with one or more embodiments.

FIG. 5 illustrates the relationship between propagation delay and impedance of the microstrip trace illustrated in FIG. 4 for a particular set of dimensions.

FIG. 6 illustrates a PCB layout top view of a differential pair of traces in an arc in accordance with one or more embodiments.

FIG. 7 illustrates a cross section of a buried microstrip trace in one or more embodiments.

FIG. 8 illustrates the relationship between propagation delay and impedance of the buried microstrip trace illustrated in FIG. 7 for a particular set of dimensions.

FIG. 9 illustrates a flowchart in accordance with one or more embodiments of the invention.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

In general, embodiments of the claimed invention relate to transmission lines and transmission line features. Specifically, embodiments of the invention relate to manipulation of propagation delays in microstrip transmission lines by adjusting a trace width of one or more traces.

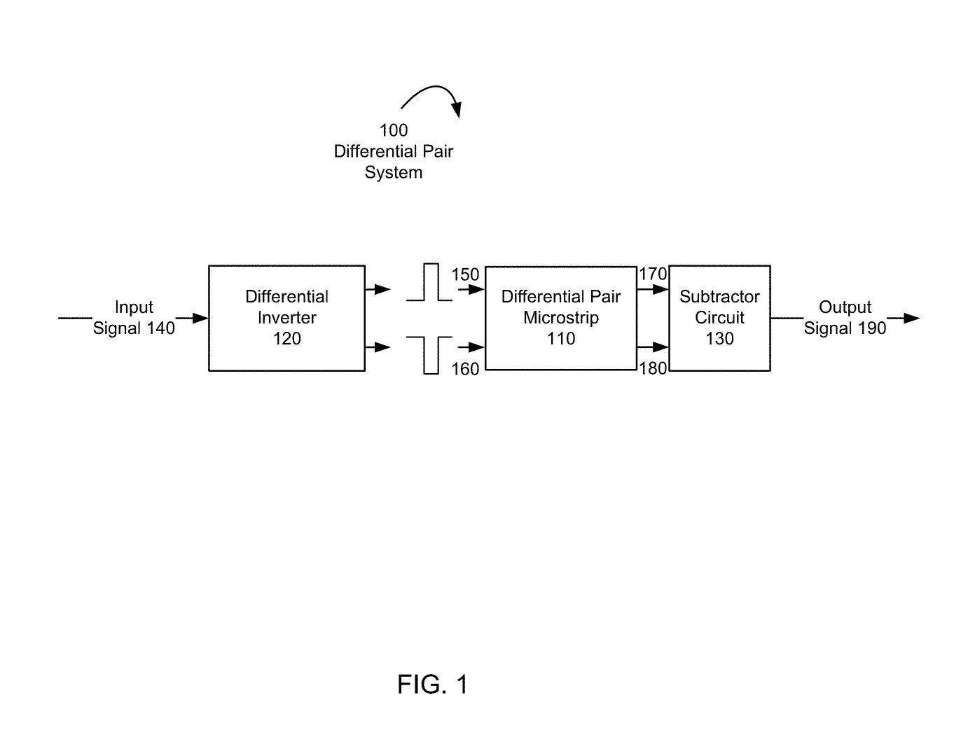

FIG. 1 shows a block diagram of a system in accordance with one or more embodiments. In one or more embodiments, as shown in FIG. 1, a microstrip system (100) includes a differential pair of traces (110), a differential inverter (120), and a subtractor circuit (130) on a printed circuit board (PCB). An input electric signal (140) may be transmitted to the differential inverter (120), which transmits the input signal (140) as it is to one trace (150) of the differential pair of traces (110) and the input signal inverted (e.g., 1 Volt inverted to −1 Volt) to the other trace (160) of the differential pair (110). The subtractor circuit (130) may respond to the electrical difference between the two traces (170, 180), and recover the original signal as output (190).

The differential inverter (120) and the subtractor circuit (130) may be implemented by standard electronic components used for circuits on a printed circuit board (PCB), generally soldered on the PCB, such as capacitors, resistors or active devices.

While FIG. 1 shows a specific configuration of components, other configurations may be used without departing from the scope of the invention. For example, various components may be combined to create a single component. As another example, the functionality performed by a single component may be performed by two or more components.

The traces of the differential pair (110) have finite signal propagation velocities, thus requiring finite times to propagate a specific distance. This may give rise to a timing mismatch between the traces of the differential pair (110) due to any difference in dimension between the traces, introducing differing signal propagation times. For example, PCB features such as integrated circuit pin out, device placement, transmitter and receiver pin orientation and location, and others may force the traces to be routed in a serpentine manner and/or change trace directions, leading to different lengths and different propagation times. With high speed signaling, even slight length differences on the order of 1/1000th of an inch may introduce notable timing variation between the traces.

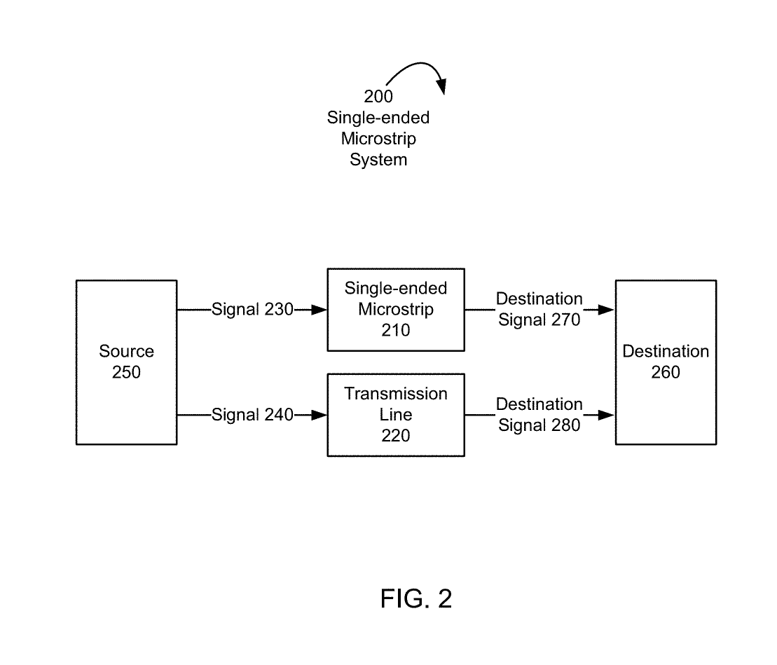

FIG. 2 shows a block diagram of a system in accordance with one or more embodiments. In one or more embodiments, as shown in FIG. 2, a microstrip system (200) includes signal sources (250), destinations (260), at least two signals (230, 240), at least one single ended microstrip or buried microstrip (210), and at least one other transmission line (220), microstrip or otherwise on a printed circuit board (PCB). Input electric signal (230) originating from a source (250) may be transmitted on a single ended microstrip (210), which transmits the input signal (230) to a destination (260). Another electric signal (240) originating from a source (250) may be transmitted on a transmission line (220) to a destination (260). The destination signals (270, 280) may have timing requirements required by the destination (260) with respect to one and the other. By way of example, the destination signals (270, 280) may be a clock and data signal, which require propagation time matching in order to meet the destination (260) timing requirements.

The source (250) and the destination (260) may be implemented by standard electronic components used for circuits on a printed circuit board (PCB), generally soldered on the PCB, such as capacitors, resistors or active devices.

While FIG. 2 shows a specific configuration of components, other configurations may be used without departing from the scope of the invention. For example, various components may be combined to create a single component. As another example, the functionality performed by a single component may be performed by two or more components.

Similarly to the differential pair of the traces (110), due to different propagation times of the transmission lines (210, 220), the destination signals (270, 280), sent from the source (250), arrive at the destination (260) at different times. By way of example, the destination signals (270, 280) may be a clock and data signal, in which case the phenomenon is known as “clock skew”.

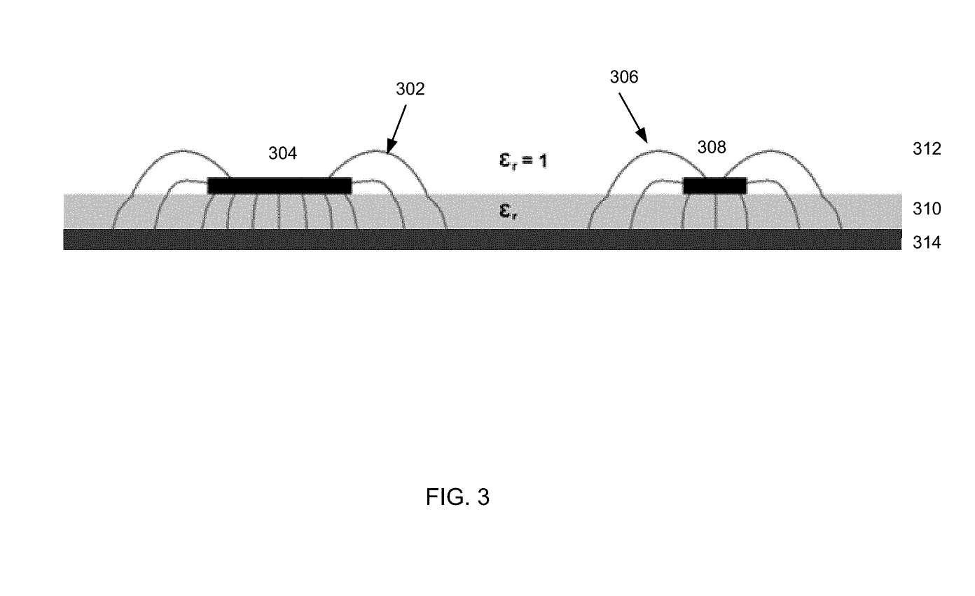

In one or more embodiments, the signal propagation time of a microstrip or buried microstrip trace may be adjusted by adjusting a width of the trace. The signal propagation time of a trace is determined by the dimensions and materials of the trace. For a microstrip and buried microstrip the trace width also contributes to propagation time. FIG. 3 illustrates an example of electric field lines (302) for a wide microstrip trace (304) on the left, and the electric field (306) for a narrow trace (308) on the right. Due to the inhomogeneity of the material surrounding the traces (304, 308), the electric field fringing out of the side of the trace (304) passes through the free space or air (312) and then the layer of dielectric material (310) to the reference plane (314). The layer of dielectric material may include, for example, solids such as plastics, ceramics, glass, or other non-conductive materials.

Towards the middle of the trace (304), the electric field may pass only through the layer of dielectric material (310), directly to the reference plane (314). Signal propagation time is directly related to the dielectric constant of the material the electric field occupies. Accordingly, a narrow trace (308) may have the electric field fringing largely in the free space or air (312) above the trace (306) rather than through the layer of dielectric material (310). Conversely, a very wide trace (304) may have the electric field (302) nearly completely contained within the layer of dielectric material (310), as in a stripline trace. As described in more detail later, the width of the microstrip traces (304, 308) vary the dielectric constant seen by the electric field, and consequently the propagation times.

The propagation velocity of such a trace may be derived as:

$${v}_{p} = \frac{c}{\sqrt{{μ}_{r} {ɛ}_{r}}} ,$$

where c is the speed of light, μᵣ is the relative magnetic permeability of the layer of dielectric material (310), and εᵣ is the relative permittivity of the layer of dielectric material (310). For dielectric materials used in PCBs, μᵣ is typically taken as 1. As such, the propagation velocity may be simply dependent on the relative permittivity of the layer of dielectric material (310). However, as mentioned earlier, a microstrip trace (304) does not have homogenous dielectric materials surrounding the trace (304). Instead, the relative permittivity of the dielectric material is a combination of that of the free space or air (312) on one side, and the layer of dielectric material (310) on the other. This is the dielectric constant, and is also called the effective relative permittivity, ε_{eff}. For most practical microstrip PCB designs with very thin dielectric materials (on the order of 2.5 mils), the quasi-transverse electromagnetic (TEM) approximation can be assumed. As such, ignoring the frequency dependence of the dielectric constant, a valid approximation for the effective dielectric constant of microstrips where 1<εᵣ≦16 and 0.25≦w/h≦6 (which is typically true in practical PCBs) is given as:

$${ɛ}_{eff} = \frac{{ɛ}_{r} + 1}{2} + \frac{{ɛ}_{r} - 1}{2} {( 1 + 12 \frac{h}{{w}_{e}} )}^{- \frac{1}{2}} + ξ - 0.217 ( {ɛ}_{r} - 1 ) \frac{t}{\sqrt{{w}_{e} h}} , \\ where \text{:}$$

$$ξ = \{ \begin{matrix}0.02 ( {ɛ}_{r} - 1 ) {( 1 - \frac{w}{h} )}^{2} & , \frac{w}{h} < 1 \\ 0 & , \frac{w}{h} > 1\end{matrix} , \\ {w}_{e} = \{ \begin{matrix}w + 0.398 t ( 1 + ln \frac{4 π w}{t} ) & , \frac{w}{h} \leq \frac{1}{2 π} \\ w + 0.398 t ( 1 + ln \frac{2 h}{t} ) & , \frac{w}{h} > \frac{1}{2 π}\end{matrix} .$$

Considering this relationship, in one or more embodiments of the invention, the width of microstrip traces may be adjusted for the purpose of propagation delay matching by adjusting the effective dielectric constant and thus propagation velocity to compensate for length differences and match propagation times.

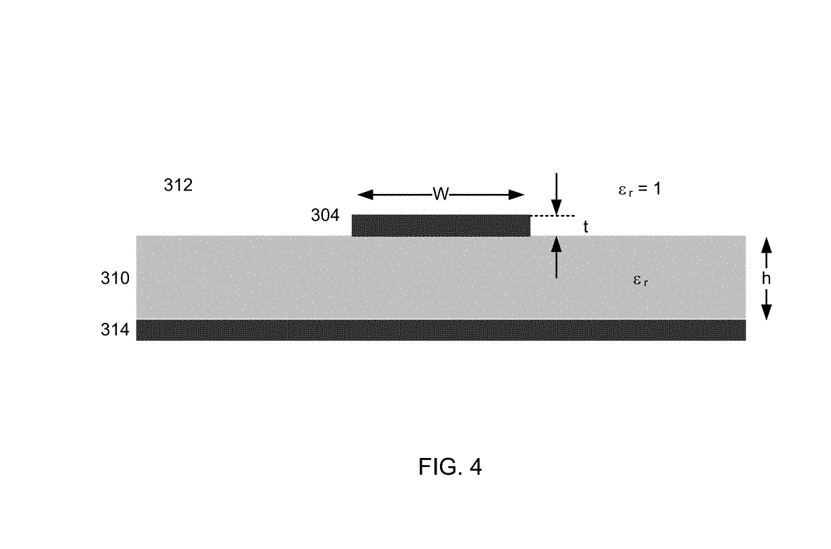

FIG. 4 illustrates a cross section view of a microstrip trace (304) of a width w and a thickness t (in the air or free space (312)) disposed on a layer of dielectric material (310) of a thickness h and a dielectric constant εᵣ, referenced to a conductive reference plane (314).

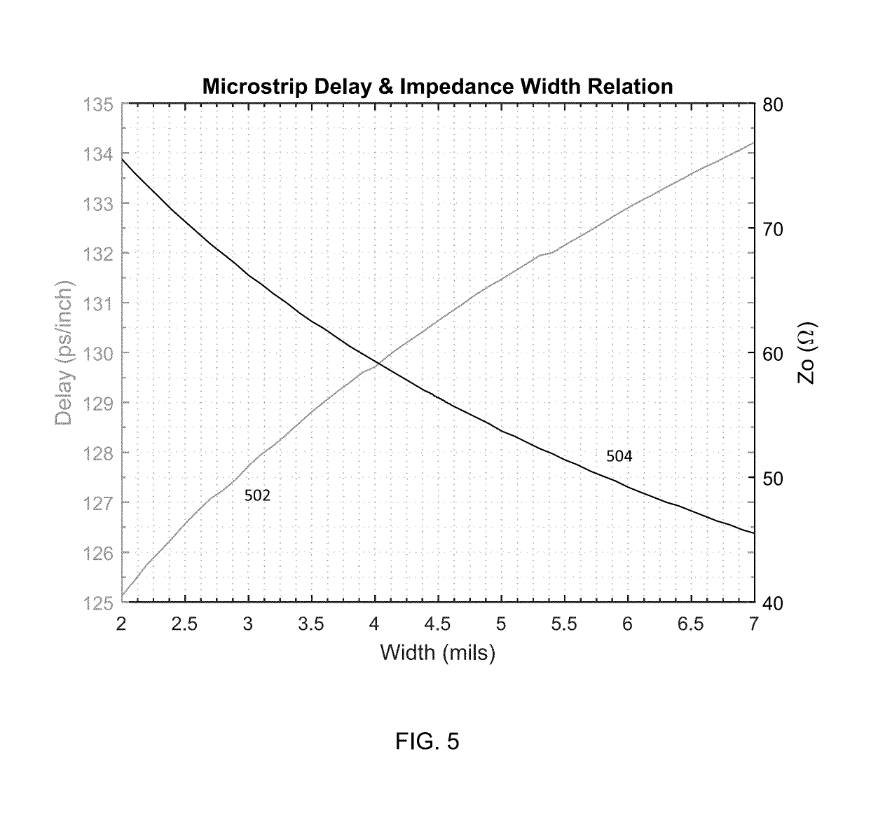

FIG. 5 illustrates a propagation delay (502) per inch of the microstrip trace (304) and the impedance (504) of the microstrip trace (304) made of 1 oz copper, disposed on a conductive reference plane (314) with a layer of dielectric material (310) of a thickness h 3.2 mil and a dielectric constant 3.47, illustrated in FIG. 4, versus the width of the microstrip trace (304). The results illustrated in FIG. 5 have been calculated by a commercial 2-dimensional electromagnetic field solver.

FIG. 5 shows that varying the width of the microstrip trace (304) may significantly affect the propagation delay (502). However, the impedance (504) of the microstrip trace (304) may be also affected and must be within a controlled range defined by design constraints, thus limiting the range of width that may be used.

By way of example of one or more embodiments, a nominal 100 Ohm differential microstrip trace width for the example dimensions can be taken as 4.5 mils and a differential pair of traces may be mismatched by a length on the magnitude of 10 mils. In order to compensate for the length mismatch, the width of the individual microstrips may be adjusted over a given length of trace. For example, the microstrip trace width of a 3-inch long segment of microstrip trace may be adjusted to compensate for 10 mils of length mismatch.

FIG. 5 shows that for the given dimensions, the nominal microstrip trace of a width 4.5 mils may have a propagation delay over 3 inches of 391.9 ps, an additional propagation delay over another 10 mils of 1.3 ps, and an impedance of 56.4 Ohm. FIG. 5 also shows a microstrip trace widened to a width 4.62 mils may have a propagation delay over 3 inches of 392.6 ps and an impedance of 55.7 Ohm. A microstrip trace narrowed to a width 4.38 mils may have a propagation delay over 3 inches and 10 mils of 392.6 ps and an impedance of 57.0 Ohm.

Furthermore, the calculated results from a commercial simulator indicate that the losses of the individual microstrips may have not significantly changed. In this specific example, the loss over a 3-inch segment of the nominal width microstrip trace has been calculated as 3.6640 dB, while the loss over a 3-inch segment of the adjusted widths microstrip traces has been calculated as 3.5556 dB and 3.6912 dB, respectively. Such a small difference in loss as 0.1 dB may be inconsequential for most applications.

It should be noted that in the example the width of the widened microstrip and the narrowed microstrip have been adjusted such that the 100 Ohm differential impedance has not been changed by this adjustment. That is, one trace width is increased while the other is decreased. In one or more embodiments, the entire adjustment may also be applied to a single trace.

In one or more embodiments, a slight width modification to a microstrip trace over a defined length section may be used to correct mismatches in propagation delays. The defined length section may be the entire length of the microstrip trace such that there are no impedance discontinuities, or a portion of the microstrip trace as a length mismatch occurs (e.g., a curve, a corner).

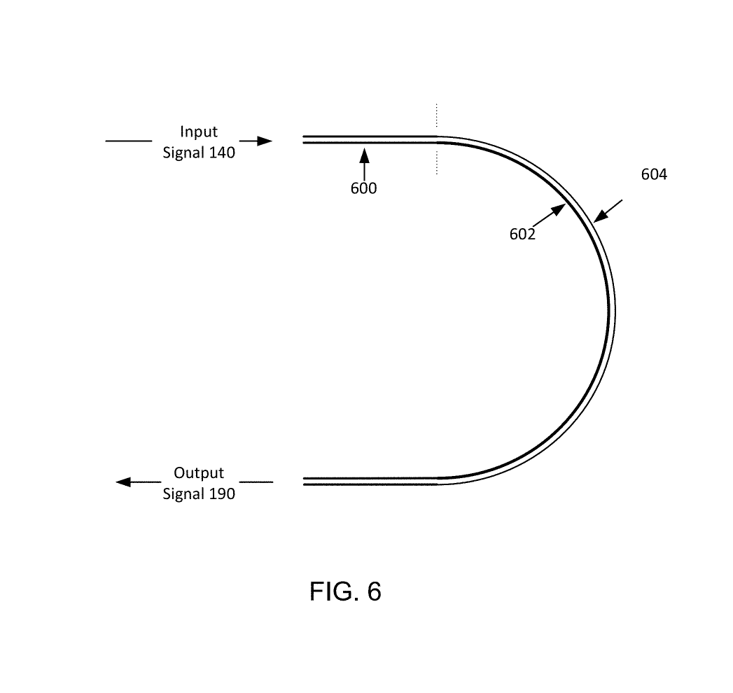

FIG. 6 illustrates a PCB layout top view of a differential pair of traces (600) in an arc. Since the trace on outside of the arc (604) is longer than the trace inside the arc (602), there is a length mismatch, introducing a propagation time mismatch. The width of the longer trace (604) may be narrowed and the width of the shorter trace (602) may be widened over a defined region, such that the propagation times through the traces (602) and (604) are matched.

The example of the differential pair of traces in an arc is shown for the purpose of illustrations only. Accordingly, the scope of the invention should not be considered limited to this specific number of traces or this specific configuration.

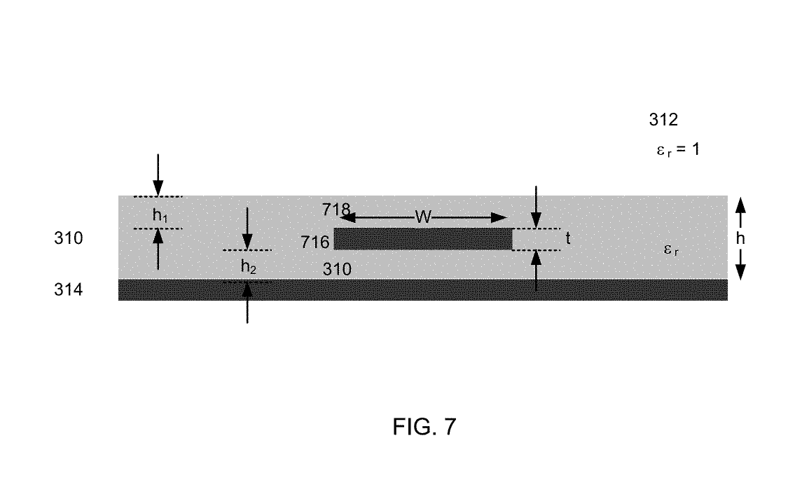

In one or more embodiments, a propagation delay matched trace may be buried in the layer of dielectric material (310). A buried microstrip (716) is similar to the microstrip trace (304), except it also has a layer of dielectric material (718) above the trace (716), as illustrated in FIG. 7.

FIG. 7 illustrates a cross section view of a buried microstrip (716) of a width w and a thickness t disposed in a layer of dielectric material (718) of a thickness h₁ above the microstrip (716) of a thickness h₂ below, and a dielectric constant εᵣ, referenced to conductive reference plane (314).

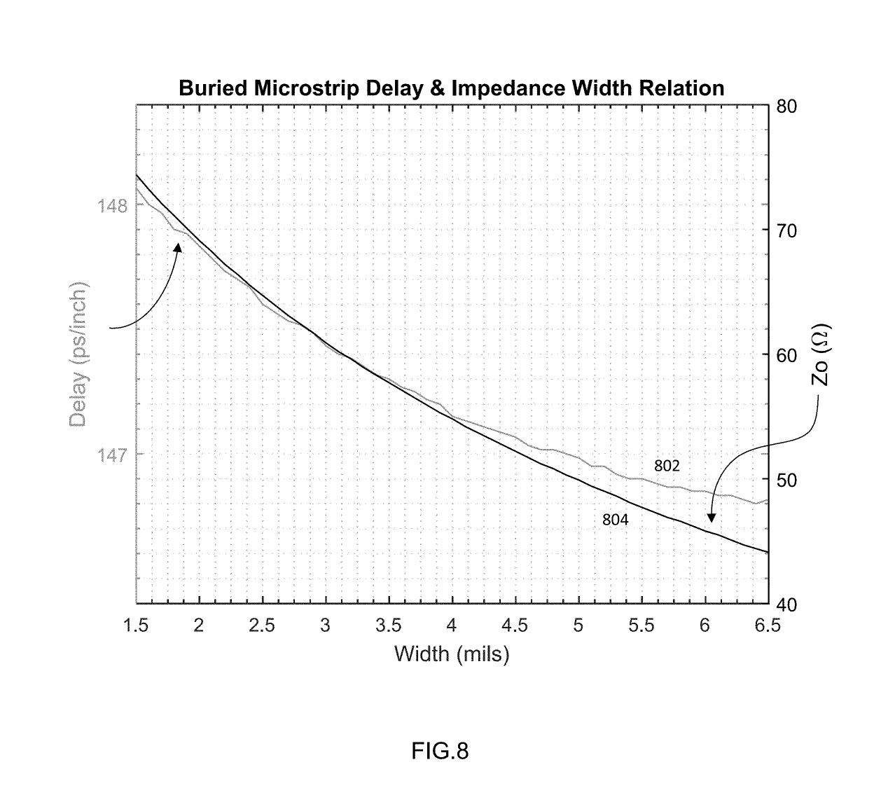

FIG. 8 illustrates a propagation delay (802) per inch of the buried microstrip (716) and the impedance (804) of the buried microstrip of 1 oz copper (716), disposed on a conductive reference plane (314) with a layer of dielectric material (718) of a thickness h₁ above the buried microstrip (716) 3.16 mils, a thickness h₂ below the buried microstrip (716) 3 mils, and a dielectric constant 3.22, illustrated in FIG. 7, versus the width of the buried microstrip (716). The results illustrated in FIG. 8 have been calculated by a commercial 2-dimensional electromagnetic field solver.

FIG. 8 shows that varying the width may affect the propagation delay (802). Again, the impedance (804) of the trace may be also affected and must be within a controlled range defined by design constraints, thus limiting the range of width that can be used. By way of an example, a nominal 100 Ohm differential buried microstrip trace width for the example dimensions can be taken as 4mils and a differential pair of traces may be mismatched by a length on the magnitude of 10 mils. FIG. 8 shows that for the example dimensions a nominal buried microstrip trace of a width 4 mils may have a propagation delay over 6 inches of 882.9 ps, an additional propagation delay over another 10 mils of 1.5 ps, and an impedance of 54.8 Ohm. FIG. 8 further shows a microstrip trace widened to a width 4.52 mils may have a propagation delay over 6 inches and 10 mils of 883.8 ps and an impedance of 52.1 Ohm. A microstrip trace narrowed to a width of 3.48 mils may have a propagation delay over 6 inches of 883.8 ps and an impedance of 57.8 Ohm.

Those skilled in the art will appreciate that the widths of the widened microstrip trace and the narrowed micro strip trace have been changed such that the differential impedance is minimally changed, with the original impedance of 100.3 Ohms becoming 100.6 Ohms. In one or more embodiments, the entire adjustment may also be applied to a single trace.

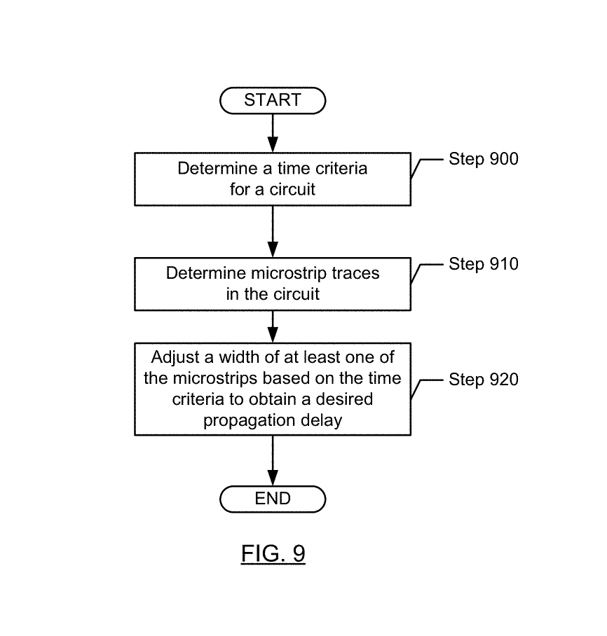

FIG. 9 illustrates a flowchart in accordance with one or more embodiments of the invention. One or more of the steps in FIG. 9 are described below as a method of propagation delay matching of a microstrip or buried microstrip transmission line, discussed above in reference to FIGS. 1-6. However, those skilled in the art would appreciate that the steps may be implemented by other components without departing from the scope of the invention. In one or more embodiments of the invention, one or more of the steps shown in FIG. 9 may be omitted, repeated, and/or performed in a different order than the order shown in FIG. 9. Accordingly, the scope of the invention should not be considered limited to the specific arrangement of steps shown in FIG. 9.

Initially, in STEP 900, time criteria for a circuit of the transmission line device may be determined. For example, in one or more embodiments of the invention, the time criteria may be based on a differential pair of traces, using two adjacent traces as a differential pair or synchronized with a clock source.

In STEP 910, one or more traces of the circuit may be determined to be microstrips. Two traces may form a differential pair of traces. One trace may form a single-ended trace. Further, the traces may be determined to be buried microstrips.

In STEP 920, a width of at least one of the microstrips is adjusted based on the time criteria to obtain a desired or matched propagation delay (i.e. propagation delay may be adjusted). The physical length of the overall traces remain unchanged since no trace lengthening with serpentines is necessary for the propagation delay matching and as such impedance discontinuities, which may cause reflections and deteriorate signal integrity especially in differential microstrips, may be avoided.

From the above disclosure, one or more embodiments of the invention make it possible to use a slight width modification to individual microstrips over a defined length to correct length mismatches in terms of propagation delay. The defined length may be the entire length of the microstrip such that there are no impedance discontinuities, or the width modification may apply to one or more portions (segments) of the microstrip that introduce the length mismatch (e.g., a curve or corner), or any other portion of the microstrip. Furthermore, according to one or more embodiments, the width of traces may be adjusted as a mismatch occurs, instead of correcting length mismatches in a single lump. For example, in the case of a differential pair, the width of the microstrips may be adjusted where the length mismatch occurs, thus canceling it out as it happens. This allows the signals within the differential pair to stay in phase. In addition to this, adjusting the width of traces requires a negligible amount of room where as meandering or serpentines require open areas to implement. Therefore, the complexity of microstrip traces may be reduced. Such simplified structures may be pre-designed and eventually be built into a computer-aided design (CAD) layout tool such that no manual intervention would be required.

While the invention has been described with respect to a limited number of embodiments, those skilled in the art, having benefit of this disclosure, will appreciate that one or more embodiments may be devised without departing from the scope of the invention as disclosed herein. Accordingly, the scope of the invention should be limited only by the attached claims.

What is claimed is:

1. A differential pair propagation delay matched microstrip transmission line manufactured on a printed circuit board (PCB) comprising:
a first trace comprising a strip of conductor in air;
a second trace comprising a strip of conductor in the air positioned adjacent to and closely spaced apart from the first trace;
a conductive reference plane disposed adjacent the first trace and the second trace; and
a layer of dielectric material that separates the first trace and the second trace from the conductive reference plane, such that electric fields fringing out of the first trace and second trace pass through the air and the layer of dielectric material;
wherein a width of at least one of the first trace and the second trace is adjusted to match signal propagation times of the first and second traces.

2. The differential pair propagation delay matched microstrip transmission line of claim 1, wherein the microstrip is a buried microstrip with a layer of dielectric material on the side of the first and second traces opposite to the conductive reference plane.

3. The differential pair propagation delay matched microstrip transmission line of claim 1, wherein widths of one or more of a plurality of length sections of the first trace and/or the second trace are adjusted to match propagation times of the first and second traces.

4. The propagation delay matched microstrip transmission line of claim 3, wherein the widths are adjusted such that length mismatches are counteracted as they occur along the transmission line.

5. The propagation delay matched microstrip transmission line of claim 3, wherein the differential impedance of the first trace and the second trace remain unchanged upon adjusting the widths.

6. The propagation delay matched microstrip transmission line of claim 3, wherein the single ended impedances of the first trace and the second trace remain within a controlled range defined by design constraints upon adjusting the widths.

7. A single-ended propagation delay matched microstrip transmission line manufactured on a printed circuit board (PCB) comprising:
a trace comprising a strip of conductor in air;
a conductive reference plane disposed adjacent the trace; and
a layer of dielectric material that separates the trace from the conductive reference plane, such that the electric field fringing out of the trace passes through the air and the layer of dielectric material;
wherein a width of the trace is adjusted to match signal propagation time thereof with another signal.

8. The single-ended propagation delay matched microstrip transmission line of claim 7, wherein the microstrip is a buried microstrip with a layer of dielectric material on the side of the trace opposite to the conductive reference plane.

9. The single-ended propagation delay matched microstrip transmission line of claim 7, wherein widths of one or more of a plurality of length sections of the traces are adjusted.

10. The single-ended propagation delay matched microstrip transmission line of claim 7, wherein the impedance of the trace remains within a controlled range defined by design constraints upon adjusting the width of the conductor.

11. A method of propagation delay matching a microstrip transmission line, comprising:
determining a time criteria for a circuit;
determining one or more traces in the circuit to be microstrips; and
adjusting a width of at least one of the microstrip traces based on the time criteria to obtain a desired propagation delay.

12. The method of claim 11, wherein the microstrip is a buried microstrip.

13. The method of claim 11, wherein adjusting the width of at least one of the traces comprises adjusting a width of at least one length section of the microstrip transmission line.

14. The method of claim 11, wherein the time criteria is the desired propagation delay for two adjacent traces forming a differential pair.

15. The method of claim 11, wherein the time criteria is a clock skew for the circuit.

16. The method of claim 11, wherein the one or more types of traces may be a differential pair of traces or single-ended traces.

17. The method of claim 11, wherein impedance of the traces remain within a controlled range defined by design constraints upon adjusting the width.
